(19) United States
(12) Patent Application Publication
(10) Pub. No.: US 2019/0378948 A1
(43) Pub. Date: Dec. 12, 2019

(54) MULTIJUNCTION SOLAR CELL WITH REAR-SIDE GERMANIUM SUBCELL AND THE USE THEREOF

(71) Applicant: FRAUNHOFER-GESELLSCHAFT ZUR FÖRDERUNG DER ANGEWANDTEN FORSCHUNG E.V., Munich (DE)

(72) Inventors: Frank DIMROTH, Gundelfingen (DE); David LACKNER, Denzlingen (DE)

(73) Assignee: Fraunhofer-Gesellschaft zur Förderung der angewandten Forschung e.V., Munich (DE)

(21) Appl. No.: 16/478,386

(22) PCT Filed: Dec. 19, 2017
(86) PCT No.: PCT/EP2017/083570

§ 371 Date: Jul. 16, 2019

(30) Foreign Application Priority Data
Jan. 18, 2017 (DE) 10 2017 200 700.1

(51) Int. Cl. H01L 31/0687; H01L 31/02

(52) U.S. Cl. CPC H01L 31/0687; H01L 31/02021; H01L 31/02008

(57) ABSTRACT

Multijunction solar cells are provided having at least four p-n junctions with a rear-side germanium subcell, orientated away from the light, and at least three subcells made of III-V compound semiconductors, disposed above the germanium subcell, the multijunction solar cells having at least one metamorphic buffer layer and at least one wafer-bonded compound and all the layers, which are disposed above the germanium subcell, comprising respectively a light-absorbing emitter- and/or base layer which comprise at least 20% indium, relative to the sum of all the atoms of group III. Furthermore, methods of using of these multijunction solar cells in space are also provided.

### CROSS-REFERENCE TO RELATED APPLICATIONS

This application is a 371 nationalization of international patent application PCT/EP2017/083570 filed Dec. 19, 2017, which claims priority under 35 USC § 119 to German patent application 10 2017 200 700.1 filed Jan. 18, 2017. The entire contents of each of the above-identified applications are hereby incorporated by reference.

### BRIEF DESCRIPTION OF THE DRAWINGS

FIG. 1 shows four different embodiments according to the invention of the multijunction solar cell (a, b, c, d);

FIG. 2 shows diagrams for the band gap and lattice constant for the embodiments according to FIGS. 1a and 1b;

FIG. 3 shows a detailed layer structure of an embodiment according to the invention; and

FIG. 4 shows a detailed layer structure of an embodiment according to the invention.

### DETAILED DESCRIPTION

The present invention relates to multijunction solar cells having at least four p-n junctions with a rear-side germanium subcell, orientated away from the light, and at least three subcells made of III-V compound semiconductors, disposed above the germanium subcell, the multijunction solar cells having at least one metamorphic buffer layer and at least one wafer-bonded compound and all the layers, which are disposed above the germanium subcell, comprising respectively a light-absorbing emitter- and/or base layer which comprise at least 20% indium, relative to the sum of all the atoms of group III. Furthermore, the present invention relates to the use of these multijunction solar cells in space.

Solar cells are used in space for supplying current to satellites. Because of their high efficiency and the high radiation stability compared with silicon, multijunction solar cells made of III-V semiconductors are hereby used predominantly. GaInP/GaInAs/Ge triple solar cells are used as standard, which cells achieve degrees of efficiency of approx. 30% under AMO conditions (i.e. in space) (see G. Strobl, D. Fuhrmann, W. Guter, V. Khorenko, W. Köstler and M. Meusel, About Azur's “3G30-Advanced” space solar cell and next generation product with 35% efficiency in 27^{th} European Photovoltaic Solar Energy Conference and Exhibition 2012, Frankfurt, Germany, p. 104-108). The solar cells are subjected, in space, to high-energy electrons, protons and other charged particles, which leads to damage to the crystals and a gradual reduction in performance. After radiation with 1 MeV electrons at a flow of 10¹⁵ cm⁻², the solar cells typically still have 85 to 90% of their original power. This is also called degree of efficiency at the end of the mission (end-of-life or abbreviated to EOL).

In order to increase the degrees of efficiency and hence the power of the solar cells, multijunction solar cells with 4, 5 or even 6 p-n junctions were developed, for example the inverted metamorphic 4-times solar cell by Solaero described by P. R. Sharps, D. Aiken, A. Boca, B. Cho, D. Chummney, A. Cornfeld, S.-S. Je, Y. Lin, C. Mackos, F. Newman, P. Patel, J. Spann, M. Stan and J. Steinfeldt in “Advances in the performance of inverted metamorphic multi-junction solar cells in 27th European Photovoltaic Solar Energy Conference and Exhibition” 2012 in Frankfurt (p. 95-98).

A bonded 5-times solar cell was presented by Boeing (P.T. Chiu, D. C. Law, R. L. Woo, S. B. Singer, D. Bhusari, W. D. Hong, A. Zakaria, J. Boisvert, S. Mesropian, R. R. King and N. H. Karam, 35.8% space and 38.8% terrestrial 5J direct bonded cells, 2014 IEEE 40th Photovoltaic Specialists Conference (PVSC), p. 11-13). These solar cells achieve higher degrees of efficiency of 33 to 35% under AMO conditions. The high degrees of efficiency cannot however be obtained unconditionally after irradiation with high-energy particles in space. Thus the inverted metamorphic solar cells of Solaero degrade more rapidly than conventional triple solar cells and, after irradiation with 1 MeV electrons at a flow of 10¹⁵ cm⁻³, achieve similar EOL degrees of efficiency as the triple solar cells based on germanium.

EP 3 012 874 A1 relates to a stack-like integrated multijunction solar cell which consists of GaInP/InP/GaInAsP/GalnAs. The GaAs subcell in the inverted metamorphic structure is hereby replaced by a very radiation-stable InP subcell and one of the GaInAs subcells by a radiation-harder GaInAsP subcell. This quadruple solar cell hence has higher radiation stability with, at the same time, higher EOL efficiency. However the lowermost GaInAs subcell is still made of a material which has a high degradation under irradiation with high-energy particles. At the same time, the production of this multijunction solar cell is expensive since the lower layers are produced typically from a substrate based on InP.

DE 10 2012 004 734 A1 describes a multijunction solar cell having at least four p-n junctions, in which a lower germanium subcell is connected via a metamorphic buffer to a GaInAs subcell. The GaInAs subcell is in turn connected via a wafer bond to a GaAs—and a GaInP subcell. The uppermost two subcells made of GaInP and GaAs are hereby grown, lattice-adapted, to form GaAs and transferred to the lower structure via wafer bonding. The individual subcells thereby have band gaps of 1.9 eV, 1.4 eV, 1.0 eV and 0.7 eV. This multijunction cell is distinguished by high degrees of efficiency but, under space conditions, has the disadvantage of lower radiation stability of the GaInAs—and GaAs subcells.

At present, the plan is to put geostationary satellites firstly into a low Earth orbit and then to convey them by means of ion drive into the GEO orbit. The solar cells are thereby subjected to a very high dose of radiation and solar cells suitable for this application must therefore be designed for radiation doses of >1E16 cm⁻². The cells known from the state of the art would, under these conditions, degrade to approx. 60% of their initial power.

Starting herefrom, it was an object of the present invention to provide multijunction solar cell structures which, even after they have been subjected to the normal high radiation doses, in space missions, of >10¹⁵ cm⁻² 1 MeV electrons, still achieve promising AMO degrees of efficiency, preferably more than 30%. In addition to increasing the efficiency and the radiation stability, these multijunction solar cells are also intended to be producible as economically as possible.

According to the invention, a multijunction solar cell having at least four p-n junctions is provided which has a rear-side germanium subcell, orientated away from the light, and at least three subcells made of III-V compound semiconductors, disposed above the germanium subcell, at least one metamorphic buffer layer and also a wafer-bonded compound for connecting subcells with a different lattice constant, all of the subcells disposed above the germanium subcell respectively comprising a light-absorbing emitter- and/or base layer, which comprise at least 20% indium, relative to the sum of all the atoms of group III.

A subcell made of III-V compound semiconductors within the scope of the present application means that the subcell consists essentially of III-V compound semiconductors, also other atoms being able to be contained up to a proportion of 1%. There are included herein, e.g. dopants, such as Zn, Se, Mg, C, Si.

The subcells disposed above the germanium subcell are abbreviated subsequently with the indices 2, 2′, 2″, 2′″ etc., the subcell directly above the germanium subcell is thereby provided with the index 2 and the subcell disposed above this subcell obtains the index 2′ and so on. This numbering is also maintained if intermediate layers, such as metamorphic buffer layers, wafer-bonded compound or tunnel diodes are disposed between the subcells.

According to a preferred embodiment of the present invention, the percentage proportion of indium, relative to the sum of all the atoms of group III (group III means the 3^{rd} main group of the periodic table of elements, i.e. B, Al, Ga, In and TI), in the emitter- and/or base layer of the subcell 2 disposed above the germanium subcell, is at least 30% and preferably at least 40%.

According to a further preferred embodiment of the present invention, the percentage proportion of indium, relative to the sum of all the atoms of group III, in the emitter- and/or base layer of the subcell 2′ and all of the subcells 2″, 2′″, . . . disposed above the subcell 2′, is at least 40% and preferably at least 45%.

According to a further preferred embodiment of the present invention, the percentage proportion of indium, relative to the sum of all the atoms of group III, in the emitter- and/or base layer of the subcell 2′, is at least 60% and preferably at least 70%.

According to a further preferred embodiment of the present invention, the percentage proportion of phosphorus, relative to the sum of all the atoms of group V (group V means the 5^{th} main group of the periodic table of elements, i.e. N, P, As, Sb and Bi), in the emitter- and/or base layer of the subcells 2 and 2′ disposed above the germanium subcell, is at least 5%, preferably at least 15%.

According to a further preferred embodiment of the present invention, the percentage proportion of phosphorus, relative to the sum of all the atoms of group V, in the emitter- and/or base layers of the subcells 2′, 2″, 2′″, . . . disposed above the subcell 2, is at least 50%, preferably at least 80%.

According to another preferred embodiment of the present invention, the thickness of the III-V subcells is 400 to 4,000 nm.

According to a further preferred embodiment of the present invention, the germanium subcell has a p-doped base layer made of germanium with a band gap of 0.67 eV at 300 K.

Another preferred embodiment of the present invention provides that the lattice constant of the germanium subcell is 5.658 angstrom.

According to a further preferred embodiment according to the invention of the present invention, the germanium subcell has a thickness of more than 4 μm, preferably more than 60 μm.

Germanium is very well suited as material for the rear-side subcell since, in comparison to other substrates, such as e.g. InP, it incurs lower costs and a p-n junction can be produced by diffusion, which makes it possible to absorb photons in the infrared range with an energy greater than the band gap of 0.67 eV and to convert them into electrical current. In addition, germanium solar cells have a very high radiation stability in space.

According to a further preferred embodiment of the present invention, the germanium subcell has a metal contact on the side orientated away from the light.

Another preferred embodiment of the present invention provides that, between the germanium subcell and the subcell 2, a metamorphic buffer layer is disposed. This converts the lattice constant of the germanium subcell into the lattice constant of the subcell 2, the lattice constant of the subcell 2 being preferably 5.75 to 5.90 angstrom and particularly preferably from 5.77 to 5.85 angstrom.

The metamorphic buffer layer can have a constant gradient in the lattice constant, or the lattice constant can be increased rapidly within the metamorphic buffer layer in steps, in this case, mismatching dislocations forming preferably at the places at which the lattice constant is increased in steps. The gradient in the lattice constant is achieved by a gradual change in composition in layers made of III-V compound semiconductors, such as AlGaInAsP, AlGaInP, GaInP, AlGaInAs, GaAsSb or GaInAs or GaInAsN, which can be n- or p-doped and which can comprise further elements such as N or B, in order to increase the crystal hardness. In order to achieve complete stress-relieving of the metamorphic buffer layer, the lattice constant within the layer can also be increased beyond the target lattice constant. The aim is to adjust the lattice constant of the subsequent subcell 2′ at the end of the metamorphic buffer layer 3 in the plane and to ensure a low density of thread- or piercing dislocations.

It was assumed in the past that metamorphic buffers which bridge a wide range of the lattice constant by several percent, lead to high dislocation densities >2E6 cm⁻² and hence to poor solar cell results. Surprisingly, according to the most recent knowledge, dislocation densities of 10⁶ cm⁻² are however even achievable with a gradient of germanium (5.658 angstrom) up to InP (5.869 angstrom). Hence a high efficiency of the multijunction solar cells, in which subcells, for example made of InP or GaInAsP, can be grown epitaxially directly on subcells made of germanium can be achieved.

According to a further preferred embodiment according to the invention, the subcell 2 and the subcell 2′ are lattice-adapted to each other. Preferably, the subcells 2, 2′ have a lattice constant of 5.75 to 5.90 angstrom and particularly preferably of 5.77 to 5.85 angstrom.

According to another preferred embodiment of the present invention, there is present, between the subcell 2′ and the subcell 2″ or between the subcell 2″ and the subcell 2′″, an electrically conductive wafer-bonded compound which preferably has a resistance of at most 5 ohm cm², particularly preferably of at most 500 mohm cm². The wafer bond forms a flush-mounted electrically conductive, optically transparent and mechanically stable compound between the subcells 2′ and 2″. This can be effected by a direct wafer bonding with covalent bonds between the semiconductor surfaces or by suitable intermediate layers, such as transparent, conductive oxides, amorphous semiconductors or suitable conductive adhesives.

A further preferred embodiment according to the invention provides that the emitter- and/or base layer of the front-side subcell, orientated towards the light, consists of AlGaInP and has a band gap energy of preferably 1.8 to 2.1 eV, particularly preferably 1.85 to 2.0 eV. The front-side subcell is preferably lattice-adapted to GaAs or germanium.

Only by combination of wafer-bonded compound and metamorphic buffer layer is it possible to connect a particularly radiation-stable, front-side AlGaInP subcell with optimum band gap energy for the multijunction solar cell to particularly radiation-stable In-containing subcells with a lattice constant of 5.75 to 5.90 angstrom and a particularly radiation-hard and economical germanium lower cell.

A preferred multijunction solar cell consists of four subcells 1, 2, 2′, 2″, the emitter- and/or base layer of the subcell 2 consisting of GaInAsP, the emitter- and/or base layer of the subcell 2′ of GaInP and the emitter- and/or base layer of the subcell 2″ of AlGaInP.

Another multijunction solar cell consists of five subcells 1, 2, 2′, 2″, 2′″, the emitter- and/or base layers of the subcells 2, 2′ consisting of GaInAsP, the emitter- and/or base layer of the subcell 2″ of AlGaInAsP and the emitter- and/or base layer of the subcell 2″ of AlGaInP.

According to a further embodiment according to the invention of the present invention, the metamorphic buffer layer between the germanium subcell 1 and the subcell 2 reflects at least 30%, in particular 70%, of the radiation in the absorption range of the subcell 2.

According to another embodiment of the present invention, tunnel diodes which connect the subcells serially are disposed between the subcells 1, 2, 2′, 2″, 2′″, . . . .

A further preferred embodiment according to the invention provides that the power of the multijunction solar cell after irradiation with 1 MeV electrons with a flow of 10¹⁶ cm⁻² degrades by less than 35%, preferably by less than 20%.

The multijunction solar cells according to the invention are used preferably in space and are used in particular for satellites.

The subject according to the invention is intended to be explained in more detail with reference to the subsequent Figures without wishing to restrict said subject to the specific embodiments shown here.

FIG. 1a shows a preferred structure of a multijunction solar cell according to the invention with 4 subcells which have respectively an emitter and base layer and also a p-n junction. In addition to the antireflection coating 5, a front-side contact 6 and a rear-side contact 7, said multijunction solar cell comprises, from bottom to top, a germanium subcell 1, a metamorphic buffer layer 3, a GaInAsP subcell 2, an InP subcell 2′, a wafer-bonded compound 4 and also a GaInP subcell 2″.

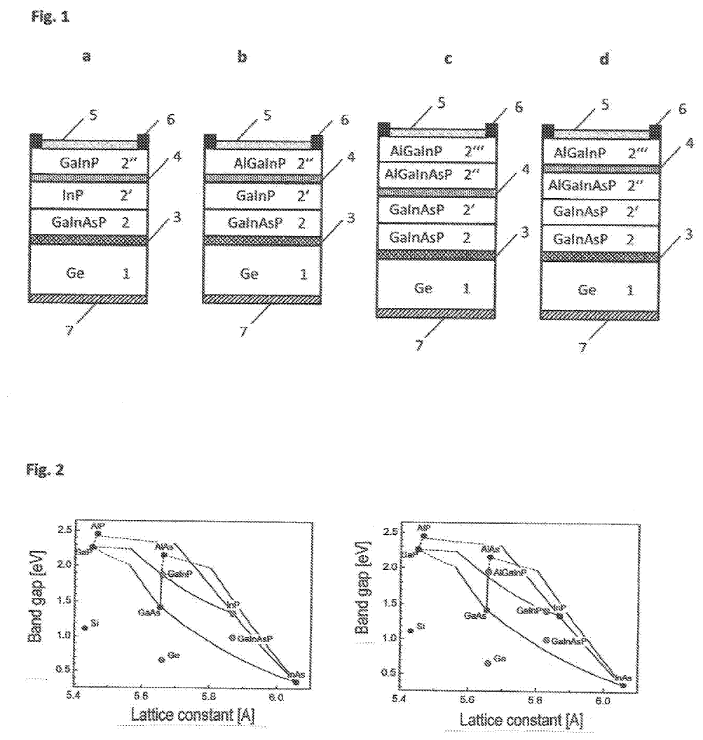

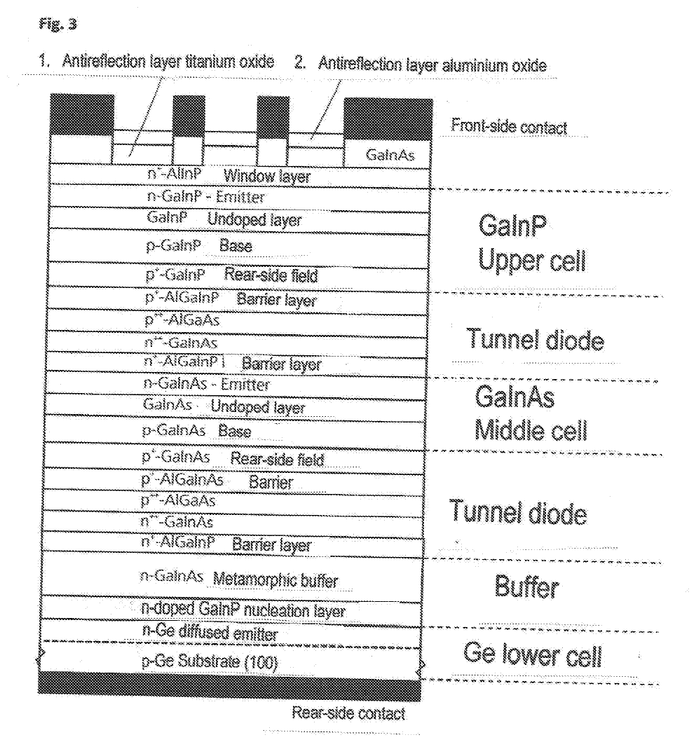

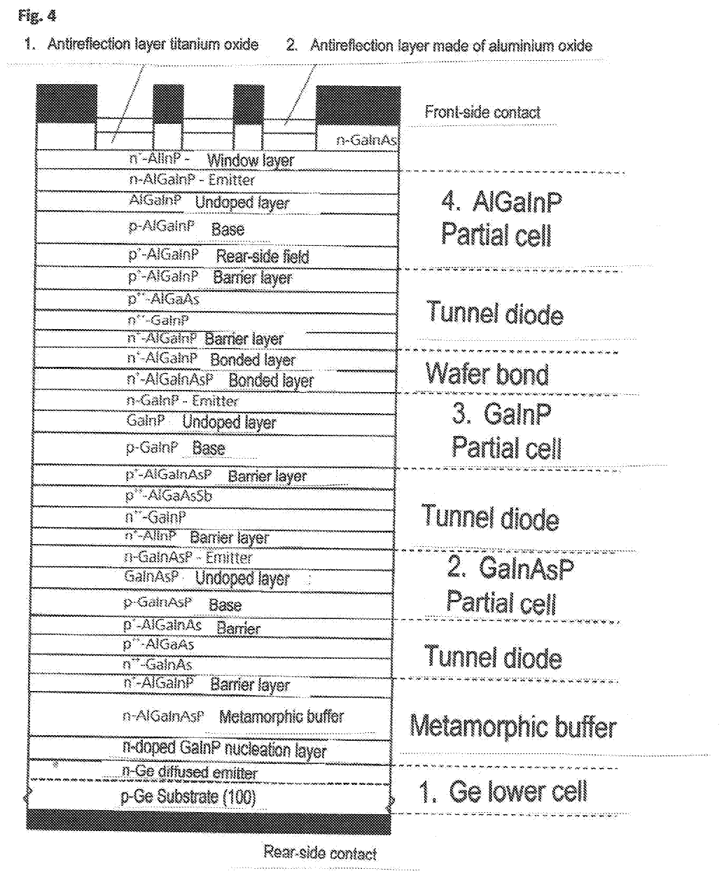

With the help of the metamorphic buffer layer 3 located on the germanium subcell 1, the lattice constant is increased from 5.658 angstrom to 5.869 angstrom (see left-hand part of FIG. 2, the lattice constants are taken from the loffe data bank: “http://www.ioffe.ru/SVA/NSM/Semicond”). At the lattice constant of 5.869 angstrom, firstly a second GaInAsP subcell 2 with a band gap energy of approx. 1.03 eV and then a third InP subcell 2′ with a band gap energy of 1.35 eV are grown in a lattice-adapted manner. The growth of the subcells 2 and 2″ can be effected in the same epitaxial process in which the metamorphic buffer layer 3 is also deposited. Alternatively, firstly only the metamorphic buffer layer 3 is deposited and the surface is then polished in a separate process in order to reduce the roughness before, in a further epitaxial process, the subcells 2 and 2″ are deposited. A fourth GaInP subcell 2″ with a band gap energy of 1.88 eV, is grown, lattice-adapted, on GaAs (5.653 angstrom) or germanium (5.658 angstrom) and subsequently is transferred to the lower structure via wafer bonding and substrate removal.

All subcells 2, 2′, 2″ have respectively an emitter and a base layer, a p-n junction being formed between the emitter and the base layer. If the emitter layer has an n-doping, then the base layer is p-doped and vice versa. Typical n-dopants comprise Si, Se, Te and p-dopants Zn, Mg and C. If emitter and base layer have the same band gap energy, then it is called a homo-solar cell, whereas if the emitter has a lower or higher band gap, compared to the base, then it is called a hetero-solar cell. The subcells 2, 2′, 2″ can be configured both as homo-, and as hetero-solar cell.

The resulting multijunction solar cell structure comprises four subcells 1, 2, 2′, 2″, with respectively one p-n junction, the materials for the emitter and/or base layer of the subcells (GaInP, InP, GaInAsP and Ge) having a high resistance relative to particle radiation in space.

FIG. 1b shows a further preferred structure of a multijunction solar cell according to the invention. In addition to the antireflection coating 5, a front-side contact 6 and a rear-side contact 7, said multijunction solar cell comprises, from bottom to top, a germanium subcell 1, a metamorphic buffer layer 3, a GaInAsP subcell 2, a GaInP subcell 2′, a wafer-bonded compound 4 and also an AlGaInP subcell 2″. Here, building on the first germanium subcell, the metamorphic buffer layer 3 is converted from a lattice constant of 5.658 angstrom to a lattice constant of 5.75 to 5.90, in particular 5.80 to 5.87 angstrom (see right-hand part of FIG. 2, the lattice constants are taken from the loffe data bank: “http://www.ioffe.ru/SVA/NSM/Semicond”). As a result, the desired band gaps for the second and third subcell can likewise be achieved by compositions of GaInAsP 2 or GaInP 2′ with high radiation stability. Furthermore, it is possible to reduce the mismatching between the germanium subcell 1 and the GaInAsP subcell 2 and consequently to achieve possibly even lower dislocation densities and substrate curvatures. In addition, the thickness of the metamorphic buffer layers 3 is lowered, if a lower difference in the lattice constant has to be overcome, which confers economic advantages. Furthermore, there result higher barriers for the, from below, third GaInP subcell 2′ at the boundary layer to the wafer-bonded compound of the uppermost AlGaInP subcell 2″. As a result of the higher band gaps of the lower three subcells, it is advantageous to adjust the uppermost subcell by the addition of Al in AlGaInP 2″ in the band gap between 1.88 and 2.1 eV.

Another preferred structure of a multijunction solar cell according to the present invention is shown in FIG. 1c. In addition to the antireflection coating 5, a front-side contact 6 and a rear-side contact 7, said multijunction solar cell comprises, from bottom to top, a germanium subcell 1, a metamorphic buffer layer 3, two GaInAsP subcells 2, 2′, a wafer-bonded compound 4, a fourth AlGaInAsP subcell 2″ and also a fifth AlGaInP subcell 2′″. The first two subcells 2, 2′ are thereby produced on the metamorphic buffer layer 3 and the uppermost two subcells are lattice-adapted to a GaAs or Ge substrate. The uppermost two subcells are in turn transferred by means of wafer-bonding and substrate removal onto the lower part of the solar cell structure.

A further preferred structure of a multijunction solar cell according to the present invention is shown in FIG. 1d. In addition to the antireflection coating 5, a front-side contact 6 and a rear-side contact 7, said multijunction solar cell comprises, from bottom to top, a germanium subcell 1, a metamorphic buffer layer 3, two GaInAsP subcells 2, 2′, an AlGaInAsP subcell 2″, a wafer-bonded compound 4 and also a fifth AlGaInP subcell 2″. The first three subcells 2, 2′, 2″ are thereby produced on the metamorphic buffer layer 3 and the uppermost subcell is grown, lattice-adapted, on GaAs or Ge substrate and subsequently transferred by means of wafer-bonding and substrate removal to the lower subcells 1, 2, 2′, 2″.

For producing the multijunction solar cell (according to FIGS. 1a and 1b), a p-n junction is produced in p-germanium by diffusion of arsenic or phosphorus from the gas phase. In addition, a nucleation layer made of n-doped GaAs or GaInP is deposited, lattice-adapted. This layer serves as front-side passivation for the first germanium subcell. On the germanium lower cell, a metamorphic buffer layer made of GaInP or AlGaInAsP is deposited, in which the lattice constant of 5.658 angstrom for Ge is converted to a lattice constant of 5.75 to 5.90, in particular 5.80 to 5.87 angstrom. In the metamorphic buffer layer, the lattice constant is increased continuously (e.g. linearly) or in steps, mismatching dislocations being formed and stress-relieving the crystal. The metamorphic buffer is configured such that at the end a stress-relieved crystal lattice with the target lattice constant and an as small as possible piercing dislocation density is present. By means of jumps in the refractive index, the buffer can be configured optionally as Bragg mirror in order to reflect non-absorbed photons into the subcell situated above. Between the germanium subcell and the metamorphic buffer layer, or between the metamorphic buffer layer and the second subcell, a tunnel diode is grown which serves to connect the subcells serially. The tunnel diode consists of degenerate n- and p-doped semiconductor layers, such as e.g. p-AlGaAs and n-GaInAs, and can optionally be surrounded by higher band gap barrier layers. Above the tunnel diode and the metamorphic buffer layer, a second In-containing subcell made of GaInAsP with a band gap energy of approx. 1.03 eV is deposited. A possible composition of the structure according to the left-hand side of FIG. 1 is Ga_{0.21}In_{0.79}As_{0.45}P_{0.55}, lattice-adapted to InP with a band gap energy of 1.03 eV. The GaInAsP absorber layer can hereby form the n-doped or the p-doped or both regions of the subcell, the doping being achieved by addition of typical doping atoms, such as Si, Se, Te, C, Mg, Zn in a concentration range of 1E16-3E18 cm⁻³. The solar cell has, furthermore, barrier layers on the front- and rear-side with a higher band gap energy in order to conduct minority charge carriers to the p-n junction. For example, a p-AlGaInAs rear-side barrier and an n-AlInP front-side barrier is used. Above the 2^{nd} subcell, a further tunnel diode is connected, which is formed for example from p-AlGaAsSb and n-GaInP. The composition of the semiconductor layers is either lattice-adapted to the 2^{nd} subcell situated therebelow or the compressive strain of a layer is compensated for by the tension strain of an adjacent layer. This “strain balancing” functions in layers which are not stress-relieved because of too little thickness. It is essential that the average lattice constant corresponds to that of the 1^{st} subcell. On the tunnel diode, a third In-containing subcell made of GaInP with a band gap energy of 1.35 eV is deposited, the GaInP layer in turn forming the n-doped emitter, the p-doped base or both and dopants, such as Si, Se, Te, C, Mg, Zn, being used in a concentration range of 1E16-3E18 cm⁻³. A possible composition of the structure according to the left-hand part of FIG. 1 is InP. The third subcell is lattice-adapted to the second subcell. Above the third subcell, an AlGaInAsP-bonded layer, preferably with a high n-doping in the range of 1E19-5E19 cm⁻³ is applied. This layer serves as front-side barrier for the 3^{rd} subcell and as connection to the 4^{th} subcell. The bonded layer is intended to have as low absorption as possible. For example, n-AlGaInAsP is used and, before the wafer bonding, is machined by means of chemical-mechanical polishing in order to ensure low surface roughness. On this lower structure of the quadruple solar cell, a 4^{th} upper cell made of (Al)GaInP with a band gap energy between 1.8 to 2.1 eV is bonded, which was grown epitaxially separately and lattice-adapted on GaAs or Ge. The wafer bond bridges the difference in the lattice constant of the third (5.75 to 5.90, in particular 5.80 to 5.87 angstrom) and fourth cell (GaAs 5.653 angstrom or germanium 5.658 angstrom). The epitaxial structure of the uppermost partial layer has in turn a highly doped n-AlGaInP-bonded layer with low roughness which is connected for example via a direct surface-activated wafer bond to the n-AlGaInAsP-bonded layer of the lower cell structure. The surface activation can be effected for example by bombarding with argon atoms in a high vacuum, as a result of which a thin amorphous bonded layer of a few nm is formed at the interface. Furthermore, the bond between the uppermost GaInP subcell and the third In-containing subcell can be effected by transparent conductive oxides or by other conductive adhesive compounds which have the necessary property of mechanical stability, optical transparency and electrical conductivity. To the bond compound, a further tunnel diode is connected made of degenerate n- and p-doped semiconductor layers, such as e.g. p-AlGaAs and n-GaInP. The average lattice constant corresponds to that of the 4^{th} subcell which consists of AlGaInP with a band gap energy of 1.88 eV. The AlGaInP absorber layer can in turn form the n-doped or the p-doped or both regions of the subcell, the doping being achieved by addition of typical doping atoms, such as Si, Se, Te, C, Mg, Zn, in a concentration range of 1E16-3E18 cm⁻³. The semiconductor structure ends on the side, orientated towards the light, with an AlInP window layer as barrier and a GaInAs contact layer.

The production of the multijunction solar cell is effected by means of epitaxial growth (preferably organometallic gas phase epitaxy) of two separate structures. The lower part of the multijunction solar cell up to the n-AlGaInAsP-bonded layer is grown epitaxially on a Ge substrate, the lattice constant being increased through the metamorphic buffer from 5.658 angstrom to 5.75 to 5.90, in particular 5.80 to 5.87 angstrom, for the 2^{nd} and 3^{rd} subcell. The uppermost 4^{th} AlGaInP subcell is grown epitaxially, in a separate epitaxial process for example lattice-adapted, in inverted layer sequence, on GaAs 5.653 angstrom or germanium 5.658 angstrom. Subsequently, the two layer sequences of the subcells 1 to 3 are connected by means of wafer-bonding to that of the 4^{th} subcell and the growth substrate made of GaAs or Ge on the 4^{th} subcell is removed. This can be effected for example via a lift-off process (chemically, via a laser process or by mechanical tension), via mechanical grinding or by wet-chemical etching processes. The processing of the multijunction solar cell comprises further steps for the production of metal contacts on the front- and rear-side and also the removal of the GaAs contact layer between the metal fingers on the front-side. Another antireflection coating is applied here also, which consists for example of two layers made of titanium oxide and aluminium oxide. Other materials for the antireflection coating comprise for example tantalum oxide, silicon nitride or magnesium fluoride.

The multijunction solar cell structure according to FIG. 1b is configured just like the structure according to FIG. 1a, only a higher band gap energy for the uppermost AlGaInP subcell is set and the lattice constant of the 2^{nd} and 3^{rd} subcell is adapted by composition changes in GaInAsP and GaInP such that an as thin as possible metamorphic buffer with the smallest possible gradient in the lattice constant can be used. This reduces damaging piercing dislocations and is economically attractive since less semiconductor material need be deposited. Furthermore it is advantageous to convert the structure not entirely to the lattice constant of InP since then higher barriers for minority charge carriers on the front- and rear-side of the 3^{rd} subcell are possible.

The multijunction solar cell structure according to FIGS. 1c and d is a further development of the structures in FIGS. 1a and b, here 5 subcells made of AlGaInP/AlGaInAsP/GaInAsP/GaInAsP/Ge being used. As a result, the theoretical degree of efficiency can be further increased. The first three or four subcells are in turn grown epitaxially on germanium and comprise a metamorphic buffer between the Ge lower cell and the GaInAsP subcell. The band gaps of the materials are chosen such that they are close to the theoretical optimum of 2.15, 1.6, 1.21, 0.9, 0.64 eV. The uppermost subcell or the uppermost two subcells made of AlGaInP and AlGaInAsP are grown epitaxially, lattice-adapted, on GaAs or Ge and then bonded to the lower cell structure. Thus a multijunction solar cell which can achieve an even higher efficiency in space under AMO conditions is produced and which uses, at the same time, only In-containing subcells with a high radiation hardness.

The examples shown here can also be extended by a further sixth subcell, as a result of which even higher AMO degrees of efficiency are theoretically possible. In this case, the band gaps and layer thicknesses of the subcells are adapted such that as high as possible a conversion efficiency of the multijunction solar cell after radiation in space is achieved.

### REFERENCE NUMBER LIST

1 germanium subcell

2, 2′, 2″, 2′″ further subcells

3 metamorphic buffer layer for changing the lattice constant

4 wafer-bonded compound

5 antireflection coating

6 front-side contact

7 rear-side contact

1. A multijunction solar cell comprising:
at least four p-n junctions with a rear-side germanium subcell orientated away from light; and
at least three subcells made of III-V compound semiconductors, disposed above the germanium subcell, at least one metamorphic buffer layer and also a wafer-bonded compound for connecting subcells with a different lattice constant, all of the at least three subcells disposed above the germanium subcell respectively comprising a light-absorbing emitter- and/or base layer, which respectively comprise at least 20% indium, relative to a sum of all atoms of group III.

2. The multijunction solar cell of claim 1, wherein the percentage proportion of indium, relative to the sum of all atoms of group III, in the emitter- and/or base layer of any of the at least three subcells disposed above the germanium subcell, is at least 30%.

3. The multijunction solar cell of claim 1, wherein the percentage proportion of indium, relative to the sum of all atoms of group III, in the emitter- and/or base layer of any of the at least three subcells and all of the subcells disposed above the subcell, is at least 40%.

4. The multijunction solar cell of claim 1, wherein the percentage proportion of indium, relative to the sum of all atoms of group III, in the emitter- and/or base layer of any of the at least three subcells, is at least 60%.

5. The multijunction solar cell of claim 1, wherein the percentage proportion of phosphorus, relative to the sum of all atoms of group V, in the emitter- and/or base layer of the at least three subcells disposed above the germanium subcell, is at least 5%.

6. The multijunction solar cell of claim 1, wherein the percentage proportion of phosphorus, relative to the sum of all the atoms of group V, in the emitter- and/or base layers of the at least three subcells disposed above the subcell, is at least 50%.

7. The multijunction solar cell of claim 1, wherein the germanium subcell has a p-doped base layer made of germanium with a band gap of 0.67 eV at 300 K and/or a lattice constant of 5.658 angstrom and/or a thickness of at least 4 μm.

8. The multijunction solar cell of claim 1, wherein the germanium subcell has a metal contact on the side orientated away from the light.

9. The multijunction solar cell of claim 1, wherein, between the germanium subcell and a corresponding subcell included in the at least three subcells, a metamorphic buffer layer is disposed, which converts the lattice constant of the germanium subcell to the lattice constant of the corresponding subcell.

10. The multijunction solar cell of claim 1, wherein the metamorphic buffer layer consists of n- or p-doped III-V compound semiconductor layers made of AlGaInAsP, AlGaInP, GaInP, AlGaInAs, GaAsSb, GaInAs, or GaInAsN.

11. The multijunction solar cell of claim 1, wherein a plurality of subcells included in the at least three subcells are lattice-adapted to each other.

12. The multijunction solar cell of claim 1, wherein an electrically conductive wafer-bonded compound is between any two of the at least three subcells.

13. The multijunction solar cell of claim 1, wherein the emitter- and/or base layer of any of the at least three subcells orientated towards the light consists of AlGaInP and has a band gap energy of 1.8 to 2.1 eV.

14. The multijunction solar cell of claim 1, wherein the multijunction solar cell consists of at least four subcells including the germanium subcell and the at least three subcells, the emitter- and/or base layer of a first respective subcell of the at least three subcells consisting of GaInAsP, the emitter- and/or base layer of a second respective subcell of the at least three subcells consisting of GaInP or InP, and the emitter- and/or base layer of a third respective subcell of the at least three subcells consisting of AlGaInP.

15. The multijunction solar cell of claim 1, wherein the multijunction solar cell consists of at least five subcells including the germanium subcell and the at least three subcells, the emitter- and/or base layer of a first and a second subcell of the at least three subcells consisting of GaInAsP, the emitter- and/or base layer of a third subcell of the at least three subcells consisting of AlGaInAsP, and the emitter- and/or base layer of a fourth subcell of the at least three subcells consisting of AlGaInP.

16. The multijunction solar cell of claim 1, wherein the metamorphic buffer layer between the germanium subcell and a subcell included in the at least three subcells reflects at least 30% of the radiation in an absorption range of the subcell.

17. The multijunction solar cell of claim 1, wherein tunnel diodes which connect the at least three subcells serially are disposed between the subcells.

18. The multijunction solar cell of claim 1, wherein power of the multijunction solar cell after irradiation with 1 MeV electrons with a flow of 1016 cm-2 degrades by less than 35%.

19. (canceled)

20. The multijunction solar cell of claim 9, wherein the lattice constant of the corresponding subcell is in a range of 5.75 to 5.90 angstrom.

21. The multijunction solar cell of claim 9, wherein the lattice constant of the corresponding subcell is in a range of 5.77 to 5.85 angstrom.
